(19) United States
(12) Patent Application Publication
(10) Pub. No.: US 2014/0138811 A1
(43) Pub. Date: May 22, 2014

(54) A SEMICONDUCTOR DEVICE INCLUDING A HEAT-SPREADING LID

(71) Applicant: NVIDIA CORPORATION, Santa Clara, CA (US)

(72) Inventors: Sunil Pandey, Santa Clara, CA (US); Jinsu Kwon, Santa Clara, CA (US); Ernie Opiniano, Santa Clara, CA (US)

(73) Assignee: NVIDIA CORPORATION, Santa Clara, CA (US)

(21) Appl. No.: 13/683,010

(22) Filed: Nov. 21, 2012

(51) Int. Cl. H01L 23/40; H01L 21/64; H01L 23/48

(52) U.S. Cl. CPC H01L 23/40; H01L 23/48; H01L 21/64
USPC 257/690; 438/122

(57) ABSTRACT

One aspect provides a semiconductor device. The semiconductor device, in this embodiment, includes a semiconductor substrate having a lower surface and an upper surface, as well as a heat-spreading lid configured to attach to the upper surface of the semiconductor substrate. In this embodiment, at least one of the semiconductor substrate or the heat-spreading lid has a plurality of openings extending entirely there through. The semiconductor device, in accordance with this aspect, further includes a plurality of fasteners operable to extend through the plurality of openings and engage the other of the semiconductor substrate or the heat-spreading lid to attach the semiconductor substrate and the heat-spreading lid.

### TECHNICAL FIELD

This application is directed, in general, to a semiconductor device and, more specifically, to a semiconductor device including a heat-spreading lid, and method for assembly thereof.

### BACKGROUND

Heat dissipation is a significant concern for present day semiconductor devices, particularly those that generate extreme amounts of heat, such as video processing semiconductor devices. What is needed in the art is an improved semiconductor device design, which is able to accommodate the aforementioned extreme amounts of heat.

### SUMMARY

One aspect provides a semiconductor device. The semiconductor device, in this embodiment, includes a semiconductor substrate having a lower surface and an upper surface, as well as a heat-spreading lid configured to attach to the upper surface of the semiconductor substrate. In this embodiment, at least one of the semiconductor substrate or the heat-spreading lid has a plurality of openings extending entirely there through. The semiconductor device, in accordance with this aspect, further includes a plurality of fasteners operable to extend through the plurality of openings and engage the other of the semiconductor substrate or the heat-spreading lid to attach the semiconductor substrate and the heat-spreading lid.

Yet another aspect provides a method for assembling a semiconductor device. The method for assembling the semiconductor device, in this aspect, includes: 1) obtaining a semiconductor substrate having a lower surface and an upper surface, 2) obtaining a heat-spreading lid, wherein at least one of the semiconductor substrate or the heat-spreading lid has a plurality of openings extending entirely there through, 3) positioning the heat-spreading lid and semiconductor substrate relative to one another, and 4) extending a plurality of fasteners through the plurality of openings to engage the other of the semiconductor substrate or the heat-spreading lid and attach the semiconductor substrate and the heat-spreading lid.

### BRIEF DESCRIPTION

Reference is now made to the following descriptions taken in conjunction with the accompanying drawings, in which:

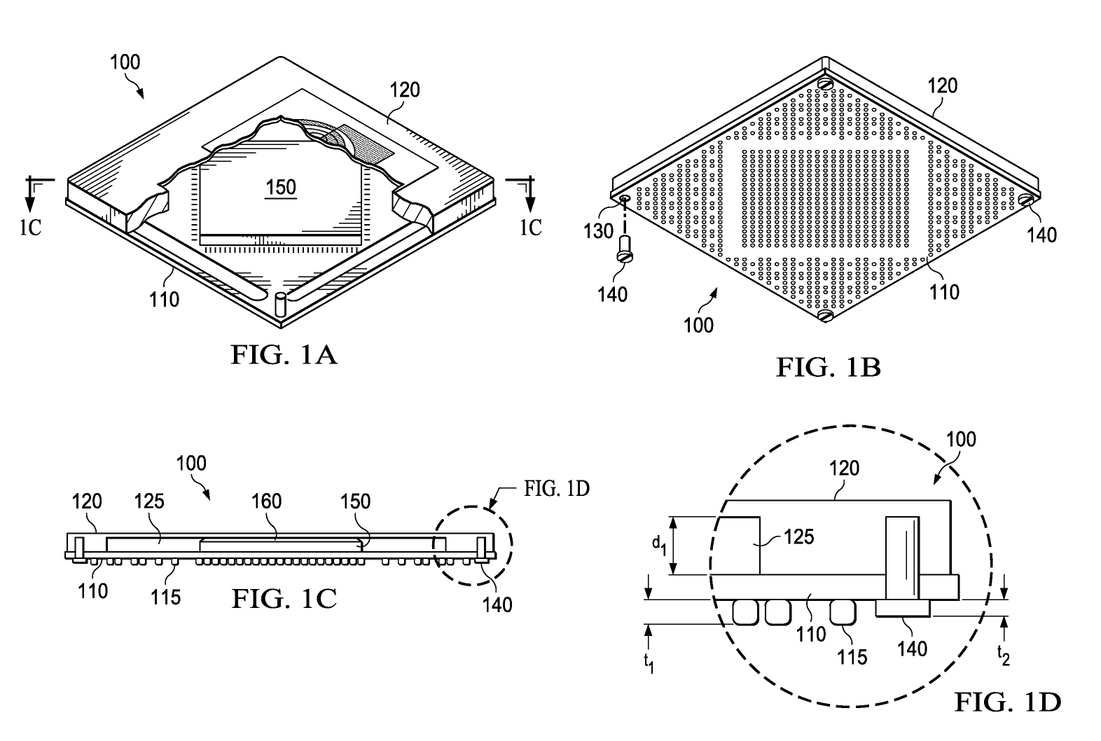

FIGS. 1A-1D illustrate aspects of a representative embodiment of a semiconductor device configured in accordance with embodiments of the disclosure;

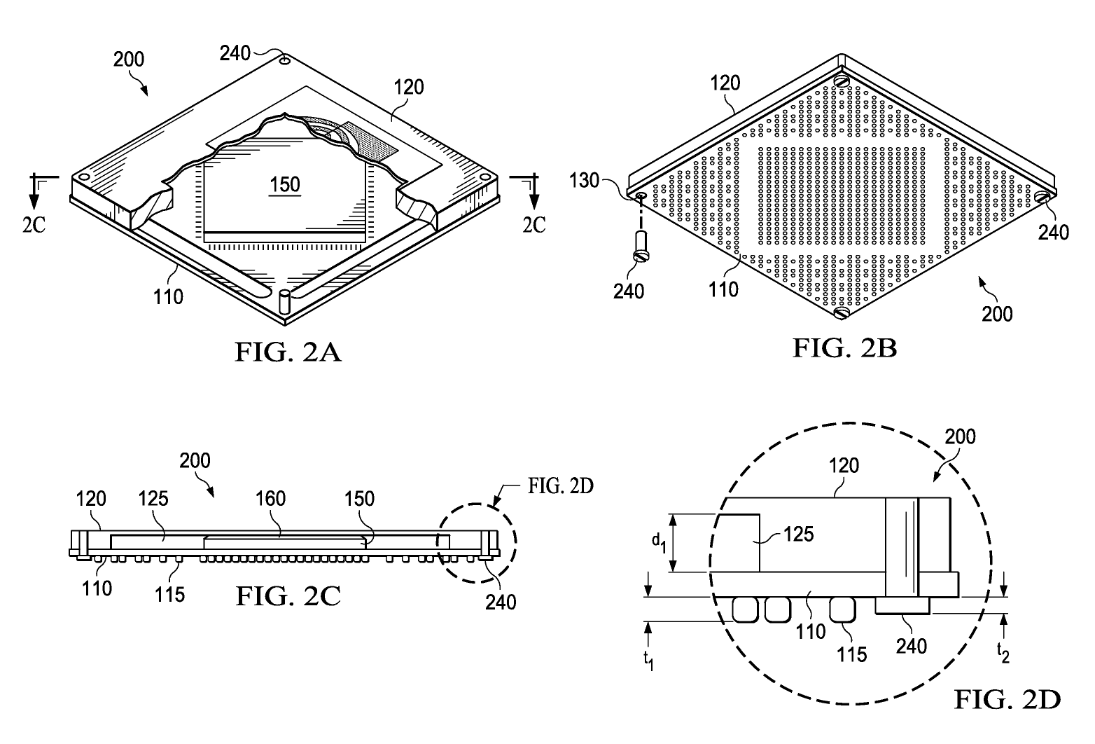

FIGS. 2A-2D illustrate alternative aspects of a representative embodiment of a semiconductor device configured in accordance with embodiments of the disclosure;

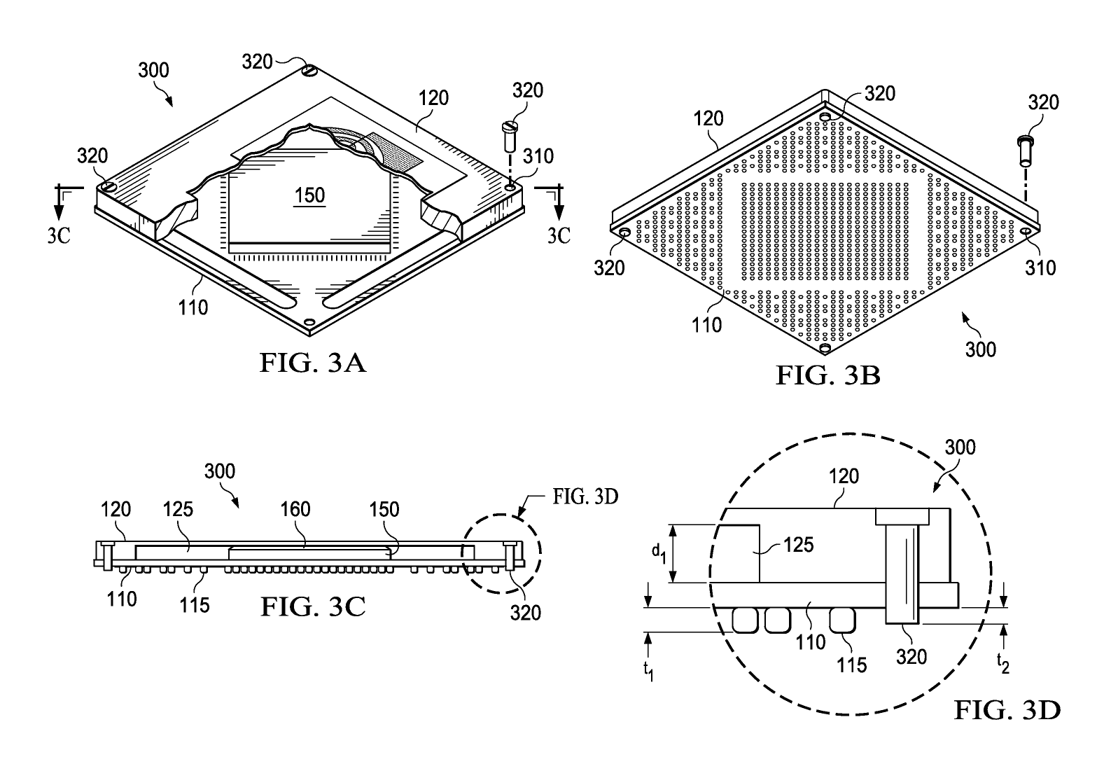

FIGS. 3A-3D illustrate aspects of an alternative embodiment of a semiconductor device configured in accordance with embodiments of the disclosure; and

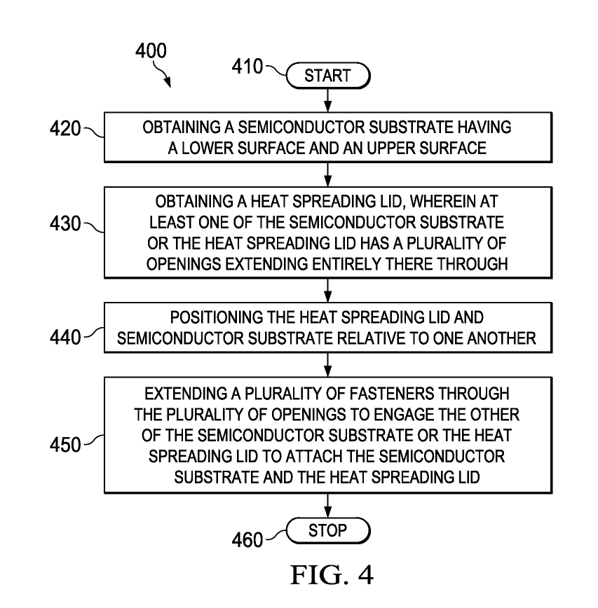

FIG. 4 illustrates a flow diagram of one embodiment of a method for assembling a semiconductor device.

### DETAILED DESCRIPTION

Before describing various embodiments of semiconductor devices, as well as methods for assembly thereof, semiconductor devices will be generally described herein.

Many present day semiconductor devices include an integrated circuit devices positioned on an upper surface of a semiconductor substrate. In the case of certain semiconductor devices, particularly those that operate at higher temperatures (e.g., video processing semiconductor devices), a heat-spreading lid is disposed over the integrated circuit device. The heat-spreading lid, in most applications, is designed to dissipate at least a portion of the heat generated by the integrated circuit device. Nevertheless, the heat-spreading lid also has the added benefit of helping reduce warpage. Typically, a thermal interface material thermally couples the integrated circuit chip and the heat-spreading lid, assisting in the transfer of heat from the integrated circuit device and the heat-spreading lid. Additionally, adhesive material (e.g., located along the periphery of the semiconductor substrate) attaches the heat-spreading lid to the semiconductor substrate, thereby attaching the heat-spreading lid to the semiconductor substrate.

The present disclosure is based, at least in part, on the recognition that high operating temperature semiconductor devices, such as might be used in video processing applications, in the very near future will generate sufficient amounts of heat to significantly weaken the adhesive attaching the heat-spreading lid to the semiconductor substrate. For example, the present disclosure has recognized that in certain situations, the adhesive is weakened to a point of failure, or where the heat-spreading lid delaminates from the semiconductor substrate. In these situations—without the thermal benefits of the heat-spreading lid—the integrated circuit chip is very susceptible to thermal failure. Moreover, the semiconductor substrate, with the integrated circuit chip mounted thereon, is very susceptible to chip warpage. As those skilled in the art appreciate, neither thermal failure nor chip warpage is particularly desirable.

The present disclosure is further based, at least in part, on the recognition that there may be a desire in the future to easily remove the heat-spreading lid from the semiconductor substrate, even after the adhesive has been applied. Within this recognition is the acknowledgment that the use of adhesive to attach the heat-spreading lid to the semiconductor substrate is problematic to the subsequent separation of the two.

Accordingly, it is fundamentally realized herein that by including a plurality of openings that extend entirely through at least one of the semiconductor substrate or heat-spreading lid, that a plurality of fasteners may extend through the plurality of openings to engage the other of the semiconductor substrate or the heat-spreading lid to attach the two. It is further realized that the fasteners can extend through a plurality of openings extending entirely through the semiconductor substrate, and thus engage the heat-spreading lid, or alternatively extend through a plurality of openings extending entirely through the heat-spreading lid, and thus engage the semiconductor substrate. The difference remains in the desire for the fasteners to enter from the semiconductor substrate side, or the heat-spreading lid side.

It is also fundamentally realized herein that the fasteners may remain exposed, and or extend (e.g., depending on the embodiment), a thickness (t₂) below the lower surface of the semiconductor substrate. This feature, unbeknownst to those currently in the art, helps reduce warpage in the semiconductor substrate. For example, in certain embodiments wherein a ball grid array having a plurality of balls attached to the bottom of the semiconductor substrate is employed, the thickness (t₂) may substantially equal a thickness (t₁) of the balls. In this scenario, the exposed portion of the fasteners may help prevent proximately located balls from deforming (e.g., crushing) due to forces placed upon the semiconductor device.

It is realized herein that for certain semiconductor devices, a threaded male fastener, and associated threaded female member, may be used to removably secure the heat-spreading lid to the semiconductor substrate. Other fasteners, including equivalents to the threaded male fastener, are within the scope of the present disclosure. For example, another embodiment might exist wherein a push pin type fastener (e.g., with characteristics of a spring) might be used. Another embodiment might exist wherein another friction type fastener might be used. The threaded female member, depending on the design chosen, may be located within the heat-spreading lid or semiconductor substrate.

Based upon the foregoing realizations, it is recognized that the heat-spreading lid and the semiconductor substrate may be secured to one another without the use of any, in certain embodiments, adhesive material. Accordingly, such a device would not experience the delamination issued discussed above, and would further provide for a much easier separation of the two when desired.

FIGS. 1A-1D illustrate aspects of a representative embodiment of a semiconductor device 100 configured in accordance with embodiments of the disclosure. Specifically, FIG. 1A illustrates a downward isometric view (e.g., with a partial cutaway of the upper surface) of the semiconductor device 100. FIG. 1B illustrates an upward isometric view of the semiconductor device 100. FIG. 1C illustrates a cross-sectional view of the semiconductor device 100 taken through the line C-C of FIG. 1A. FIG. 1D illustrates an exploded view of the area D of FIG. 1C. When referring to the drawings herein, like features are referred to using like reference designators.

The semiconductor device 100 illustrates in FIGS. 1A-1D initially include a semiconductor substrate 110. In the illustrated embodiment, the semiconductor substrate 110 includes a lower surface and an upper surface. Those skilled in the art of semiconductor device design fully understand that the semiconductor substrate 110 may comprise any material currently known, or hereafter discovered, for use as a substrate in a semiconductor device. For example, in the illustrated embodiment, the semiconductor substrate 110 comprises a printed circuit board (PCB) material. Nevertheless, the semiconductor substrate 110 should not be limited to the PCB material discussed.

Located on the lower surface of the semiconductor substrate 110, at least in the illustrated embodiment, is a ball grid array, including a plurality of balls 115. Those skilled in the art appreciate the purpose and manufacture of the plurality of balls 115. In one particular embodiment, each of the balls 115 in the ball grid array has a thickness (t₁). The thickness (t₁) may vary greatly based upon the design of the semiconductor device 100.

With further reference to FIGS. 1A-1D, positioned over, and in this embodiment attached to, the semiconductor substrate 110 is a heat-spreading lid 120. The heat-spreading lid 120 may comprise any material, and taken on any shape, that is consistent with the aspects of the present disclosure. For example, in the illustrated embodiment, the heat-spreading lid 120 comprises aluminum. In other embodiments, however, the heat-spreading lid 120 might comprise a different thermally conductive material.

The heat-spreading lid 120, in accordance with the disclosure, may include a cavity 125 therein. As illustrated in FIG. 1D, the cavity 125 is defined by the distance (d₁). The distance (d₁), in accordance with one embodiment of the disclosure, may range from about 1 mm to about 10 mm. Nevertheless, other distances (d₁) (e.g., outside of those listed) are within the scope of the present disclosure.

With further reference to FIGS. 1A-1D, a plurality of openings 130 extend entirely through the semiconductor substrate 110. In the illustrated embodiment, four openings 130 located at the four opposing corners of the semiconductor device 100 extend entirely through the semiconductor substrate 110. While four openings 130 are illustrated in the embodiments of FIGS. 1A-1D, any combination of two or more openings may be used and remain within the purview of the present disclosure.

With further reference to FIGS. 1A-1D, a plurality of fasteners 140 extend from the bottom surface of the semiconductor substrate 110, through the openings 130 in the semiconductor substrate 110, and engage the heat-spreading lid 120. In doing so, the plurality of fasteners 140 attach the heat-spreading lid 120 to the semiconductor substrate 110. The plurality of fasteners 140, in accordance with the disclosure, may comprise many different fasteners, so long as they can extend through openings in at least one of the semiconductor substrate or heat-spreading lid and engage the other of the heat-spreading lid or semiconductor substrate.

In the illustrated embodiment, the plurality of fasteners 140 are threaded male fasteners. For example, threaded male fasteners having a length ranging from about 1 mm to about 5 mm might be used. Additionally, the threaded male fasteners might have thread diameters ranging from about 1 mm to about 3 mm, and head diameter ranging from about 1 mm to about 3 mm, among others. Nevertheless, the present disclosure shall not be limited to any specific threaded male fastener size.

In the illustrated embodiment of FIGS. 1A-1D, the fasteners 140 engage threaded female members associated with the heat-spreading lid 120. For example, in one embodiment the threaded female members may be integrated into an inner surface of the heat-spreading lid 120. In another related embodiment, the threaded female members may be a threaded openings extending into, and possibly through, the heat-spreading lid 120. The threaded female members, in the embodiment shown, prevent the fasteners 140 from extending entirely through the heat-spreading lid 120. Nevertheless, as just mentioned, other embodiments exist wherein the threaded female members allow the fasteners 140 to extend entirely through, and even beyond, the heat-spreading lid 120. In the illustrated embodiment, the threaded female members are associated with a non-cavity portion (e.g., peripheral portion) of the heat-spreading lid 120. Accordingly, at least in this embodiment, the threaded female members are laterally offset from the cavity 125.

With specific reference to FIG. 1D, a portion of the fastener 140 may be exposed along the lower surface of the semiconductor substrate 110. The exposed portion, which may form at least a portion of the head of a threaded male fastener, may have an exposed thickness (t₂). The exposed thickness (t₂) may vary greatly based upon the design of the semiconductor device 100. In one embodiment, however, the exposed thickness (t₂) is substantially equal to, or just slightly less than in another embodiment, a thickness (t₁) of the balls 115. Accordingly, in one embodiment a value of the thickness (t₂) ranges from about 95% to about 100% of a value of the thickness (t₁).

As further illustrated in FIGS. 1A-1D, the semiconductor device 100 may additionally include an integrated circuit chip 150. The integrated circuit chip 150, in accordance with the disclosure, may comprise any integrated circuit chip. Of particular benefit to the present disclosure, however, are high operating temperature integrated circuit chips, such as video processing chips. Thermally coupling the integrated circuit chip 150 to the heat-spreading lid 120 may be a thermal interface material 160. Any thermal interface material 160 capable of helping heat transfer from the integrated circuit chip 160 is within the purview of the disclosure.

Those skilled in the pertinent art will appreciate that the semiconductor device 100, while discussed in terms of components necessary to describe embodiments of the invention, is representative of a semiconductor device of diverse configuration and complexity.

Turning briefly to FIGS. 2A-2D, illustrated is an alternative embodiment of a semiconductor device 200 manufactured in accordance with the principles of the present disclosure. The semiconductor device 200 is substantially similar to the semiconductor device 100, with the exception that the fasteners 240 of the semiconductor device 200 extend entirely through the heat-spreading lid 120. Accordingly, a portion of the fasteners 240 appear when viewing the upper surface of the heat-spreading lid 120, as opposed to the opposite in FIGS. 1A-1D.

Turning now to FIGS. 3A-3D, illustrated is yet another alternative embodiment of a semiconductor device 300 manufactured in accordance with the principles of the present disclosure. The semiconductor device 300 is very similar to the semiconductor device 100 of FIGS. 1A-1D. However, among other possible differences, the semiconductor device 300 of FIGS. 3A-3D includes a plurality of openings 310 that extend entirely through the heat-spreading lid 120. In this embodiment, a plurality of fasteners 320 extend through the openings 310 in the heat-spreading lid 120 to engage the semiconductor substrate 110, as opposed to the opposite configuration in FIGS. 1A-1D.

In the illustrated embodiment, top surfaces of the fasteners 320 are substantially flush with a top surface of the heat-spreading lid 120. Conversely, bottom surfaces of the fasteners 320, at least in this embodiment, extend a thickness (t₂) beyond a lower surface of the semiconductor substrate 110. In one particular embodiment, the thickness (t₂) is substantially equal, or slightly less than, a thickness (t₁) of the balls 115. Other embodiments exist, however, wherein top surfaces of the fasteners 320 are not flush with a top surface of the heat-spreading lid 120 (e.g., whether they extend above or below the top surface of the heat-spreading lid 120). Additional embodiments may also exist wherein bottom surfaces of the fasteners 320 extend through the semiconductor substrate 110, but remain flush with a bottom surface thereof, or only extend a portion into the semiconductor substrate 110. Such embodiments are not presently shown, but are readily understood by those skilled in the art when given the instant disclosure.

FIG. 4 is a flow diagram 400 of one embodiment of a method for assembling a semiconductor device. The method for assembling a semiconductor device begins in a start step 410 and continues on to step 420, wherein a semiconductor substrate having a lower surface and an upper surface is obtained. In a step 430, a heat-spreading lid is obtained. There is no specific order for steps 420 and 430. Accordingly, step 430 may occur before, after or simultaneously with step 420, or vice-versa. At least one of the semiconductor substrate or the heat-spreading lid obtained in steps 420 and 430, respectively, has a plurality of openings extending entirely there through. In a subsequent step 440, the heat-spreading lid and semiconductor substrate are positioned relative to one another, and in a step 450, a plurality of fasteners are extended through the plurality of openings to engage the other of the semiconductor substrate or the heat-spreading lid. In this step 450, the heat-spreading lid is attached to the semiconductor substrate. The method ends in a stop step 460.

Those skilled in the art to which this application relates will appreciate that other and further additions, deletions, substitutions and modifications may be made to the described embodiments.

What is claimed is:

1. A semiconductor device, comprising:
a semiconductor substrate having a lower surface and an upper surface;
a heat-spreading lid configured to attach to the upper surface of the semiconductor substrate, wherein at least one of the semiconductor substrate or the heat-spreading lid has a plurality of openings extending entirely there through; and
a plurality of fasteners operable to extend through the plurality of openings and engage the other of the semiconductor substrate or the heat-spreading lid to attach the semiconductor substrate and the heat-spreading lid.

2. The semiconductor device recited in claim 1, wherein the plurality of openings extend entirely through the semiconductor substrate.

3. The semiconductor device recited in claim 2, wherein the plurality of fasteners are threaded male fasteners operable to extend through the semiconductor substrate and engage the heat-spreading lid.

4. The semiconductor device recited in claim 3, further including a threaded female members associated with the heat-spreading lid and configured to engage the threaded male fasteners.

5. The semiconductor device recited in claim 4, wherein the threaded female members are integrated into an inner surface of the heat-spreading lid.

6. The semiconductor device recited in claim 5, wherein the threaded female members prevent the threaded male fasteners from extending entirely through the heat-spreading lid.

7. The semiconductor device recited in claim 5, wherein the threaded female members allow the threaded male fasteners to extend entirely through the heat-spreading lid.

8. The semiconductor device recited in claim 3, wherein the threaded male fasteners engage the heat-spreading lid, leaving a portion of the threaded male fasteners exposed along the lower surface of the semiconductor substrate.

9. The semiconductor device recited in claim 8, wherein the exposed portion of the threaded male fasteners is at least a portion of a head of the threaded male fasteners.

10. The semiconductor device recited in claim 9, further including a ball grid array disposed on the lower surface of the semiconductor substrate, wherein a thickness of one or more balls in the ball grid array substantially equal a thickness of the exposed portion.

11. The semiconductor device recited in claim 1, wherein four openings extend entirely through the at least the one of the semiconductor substrate or the heat-spreading lid.

12. The semiconductor device recited in claim 10, wherein the four openings are located at four corners of the at least the one of the semiconductor substrate or the heat-spreading lid.

13. The semiconductor device recited in claim 1, further including an integrated circuit chip located on an upper surface of the semiconductor substrate.

14. The semiconductor device recited in claim 13, further including a thermal interface material positioned between the integrated circuit chip and the heat-spreading lid.

15. The semiconductor device recited in claim 1, wherein no adhesive material physically attaches the semiconductor substrate and the heat-spreading lid.

16. The semiconductor device recited in claim 1, wherein the plurality of openings extend entirely through the heat-spreading lid, and further wherein the plurality of fasteners are threaded male fasteners operable to extend through the heat-spreading lid and engage threaded female members associated with the semiconductor substrate.

17. A method for assembling a semiconductor device, comprising:
obtaining a semiconductor substrate having a lower surface and an upper surface;
obtaining a heat-spreading lid, wherein at least one of the semiconductor substrate or the heat-spreading lid has a plurality of openings extending entirely there through;
positioning the heat-spreading lid and semiconductor substrate relative to one another; and
extending a plurality of fasteners through the plurality of openings to engage the other of the semiconductor substrate or the heat-spreading lid and attach the semiconductor substrate and the heat-spreading lid.

18. The method recited in claim 17, wherein no adhesive material physically attaches the semiconductor substrate and the heat-spreading lid.

19. The method recited in claim 17, wherein the plurality of openings extend entirely through the semiconductor substrate, and further wherein the plurality of fasteners are threaded male fasteners operable to extend through the semiconductor substrate and engage threaded female members associated with the heat-spreading lid.

20. The method recited in claim 17, wherein the plurality of openings extend entirely through the heat-spreading lid, and further wherein the plurality of fasteners are threaded male fasteners operable to extend through the heat-spreading lid and engage threaded female members associated with the semiconductor substrate.
